(19) United States
(12) Patent Application Publication
(10) Pub. No.: US 2026/0247680 A1
(43) Pub. Date: Aug. 20, 2026

(54) Method for reducing corrosion defects in a metal gate process and a semiconductor structure

(71) Applicant: Shanghai Huali Integrated Circuit Corporation, Shanghai (CN)

(72) Inventor: Yu XIA, Shanghai (CN)

(73) Assignee: Shanghai Huali Integrated Circuit Corporation, Shanghai (CN)

(21) Appl. No.: 19/182,678

(22) Filed: Apr. 18, 2025

(30) Foreign Application Priority Data
Feb. 19, 2025 (CN) 2025101874006

(51) Int. Cl. H10D 64/01; H01L 21/28; H01L 21/285; H10D 64/66; H10D 84/01; H10D 84/85

(52) U.S. Cl. CPC H10D 64/017; H10D 64/01318; H10D 64/01326; H10D 84/0172; H10P 14/43; H10D 64/667; H10D 84/85

(57) ABSTRACT

A method for reducing metal gate corrosion defects is provided. A thicker second hard mask layer is formed at the chamfer on top edge of the isolation layer between the PMOS and NMOS regions, wherein the chamfer sloping toward the NMOS region, as the deposition process creates a thicker layer around step corners. By precisely controlling the etching thickness during subsequent steps, the second hard mask layer in flat regions is removed, while the second hard mask layer at the chamfer is only partially removed, so the remaining second hard mask layer at the chamfer protects the chamfer, reducing the risk of wet cleaning solution penetrating into the metal gate during subsequent wet cleaning of the groove. The present invention addresses corrosion defects caused by chemical reactions between wet cleaning solutions and metal materials such as aluminum, significantly enhancing the performance and reliability of the semiconductor structure.

### CROSS-REFERENCE TO RELATED APPLICATION

The present invention claims the benefit of priority to Chinese Patent Application No. 202510187400.6, entitled “A METHOD FOR REDUCING CORROSION DEFECTS IN A METAL GATE PROCESS AND A SEMICONDUCTOR STRUCTURE”, filed with CNIPA on Feb. 19, 2025, the disclosure of which is incorporated herein by reference in its entirety for all purposes.

### FIELD OF THE INVENTION

The present invention relates to the field of semiconductor integrated circuit manufacturing technology, and in particular to a method for reducing corrosion defects in a metal gate process during making a semiconductor structure.

### BACKGROUND OF THE INVENTION.

The advancement of chip technology has not only advanced technological development in the society, but also enhanced the efficiency and convenience of information acquisition, thereby significantly facilitating people's daily lives. For integrated circuits made in prior times, the gates of MOS transistors typically adopted polysilicon gates. As the size of MOS transistors continues to decrease, traditional polysilicon gates reduce device efficiency due to the boron penetration effect. Additionally, unavoidable issues such as the poly depletion effect led to an increase in the equivalent gate dielectric thickness and a decrease in gate capacitance, which ultimately result in a decline in overall device performance. To meet the demand for higher performance, polysilicon gates are increasingly being replaced by metal gates to further optimize the overall chip performance.

MOS transistors include two basic types: PMOS transistor and NMOS transistor. PMOS and NMOS transistors exhibit significant differences in their working principles and electrical characteristics. The metal gates for PMOS transistors and for NMOS transistors have different structures, and their manufacturing processes employ different designs based on their specific requirements. Currently, there are two methods used to fabricate NMOS and PMOS metal gate structures in the industry. The first method includes: removing the polysilicon in both the NMOS and PMOS regions, performing a deposition-photolithography-etching process to form work function metal layers with different thicknesses in the NMOS and PMOS regions, respectively, and then filling the NMOS and PMOS regions with metal materials to form the metal gates. The second method includes: removing the polysilicon in the PMOS region, filling the PMOS region with metal material, and planarizing the surface of the PMOS region through a chemical-mechanical polishing process; then, removing the polysilicon in the NMOS region, filling the NMOS region with metal material, and planarizing the surface of the NMOS region through a chemical-mechanical polishing process. However, it was found that in the second method, when removing the polysilicon in the NMOS region, the interface at the junction of the NMOS and PMOS regions may be damaged, and a chamfer may be formed at the interface at this time. During the subsequent wet cleaning process to remove the NMOS region, the wet cleaning solution may penetrate into the PMOS metal gate along the chamfer and chemically react with the materials of the PMOS metal gate, leading to corrosion defects that seriously affect the performance and reliability of the device.

Therefore, a method for reducing corrosion defects in the metal gate process is needed to address the corrosion caused by the chamfer at the junction of the NMOS and PMOS regions and the resulting defects.

It should be noted that the above description of the technical background is solely for the purpose of providing a clear and complete explanation of the technical solution of the present invention, and to assist those skilled in the art in understanding it. It should not be assumed that the technical solutions described above are generally known to those skilled in the art merely because they are described in the background art of the present invention.

### SUMMARY OF THE INVENTION

The present invention provides a method for reducing corrosion defects in a metal gate process and a semiconductor structure.

The method for reducing corrosion defects in a metal gate process includes the following steps:
S1: providing a substrate, wherein the substrate includes a PMOS region and an NMOS region, wherein a PMOS metal gate and a P work function metal layer are formed in the PMOS region, a gate sacrificial layer is formed in the NMOS region, and an isolation layer is formed between the PMOS region and the NMOS region, wherein a sidewall and an interlayer dielectric layer are formed on the left side of the PMOS region as well as on the right side of the NMOS region;
S2: forming a first hard mask layer and a first photoresist layer sequentially on a top surface of the substrate, removing the first hard mask layer from the NMOS region by patterning the first photoresist layer as a mask to expose the gate sacrificial layer in the NMOS region, and forming a chamfer on a top of the isolation layer sloping toward the NMOS region;
S3: forming, by re-depositing the dielectric material through the chemical vapor deposition process, the second hard mask layer on the top surfaces of the gate sacrificial layer, the chamfer, a portion of the interlayer dielectric layer not covered by the first hard mask layer, and the first hard mask layer, and a thickness of the second hard mask layer at the chamfer is greater than the thickness on the first hard mask layer and the thickness of other parts of the second hard mask layer not at the chamfer;
S4: removing a portion of the second hard mask layer and the gate sacrificial layer through a patterning lithography and etch back process to form a groove in the NMOS region;
S5: depositing a metal material film in the groove to form an N work function metal layer and fill the remaining groove with an NMOS metal gate, and performing a chemical-mechanical polishing process to make the surfaces of the NMOS metal gate and the PMOS metal gate coplanar.

Optionally, the material of the P work function metal layer includes TiN, and the material of the N work function metal layer includes TiAl.

Optionally, the material of the PMOS metal gate is similar to that of the NMOS metal gate, and the material of the PMOS metal gate includes aluminum.

Optionally, the material of the first hard mask layer includes at least one of silicon oxide, silicon nitride, silicon oxynitride, tantalum nitride, or titanium nitride, and the material the second hard mask layer includes at least one of silicon oxide, silicon nitride, silicon oxynitride, tantalum nitride, or titanium nitride.

Optionally, the material of the first hard mask layer is similar to that of the second hard mask layer.

Optionally, the thickness of the second hard mask layer ranges from 1 to 10 nm.

Optionally, the steps for removing a portion of the second hard mask layer and the gate sacrificial layer through the etch back process include: removing the second hard mask layer on the first hard mask layer and the gate sacrificial layer through a first dry etching process, during which a portion of the second hard mask layer at the chamfer is retained; and then removing the gate sacrificial layer through a second dry etching process and treating the surface of the groove to remove process residues.

Optionally, the second dry etching process employs an etching method with a high etch selectivity of the gate sacrificial layer relative to the second hard mask layer.

Optionally, the material of the gate sacrificial layer includes one of amorphous silicon or amorphous carbon.

The present invention further provides a semiconductor structure, and the semiconductor structure is formed by using the method for reducing corrosion defects in the metal gate process, as described above.

In summary, the method for reducing corrosion defects in the metal gate process and the semiconductor structure provided in the present invention have the following beneficial effects: a thicker second hard mask layer is formed at the chamfer of the isolation layer between the PMOS and NMOS regions to reinforce the chamfer, due to the characteristic of the deposition process that tends to create a thicker layer at step regions. By precisely controlling the etching thickness during subsequent steps, only the second hard mask layer in the flat regions is removed, while the reinforcing material at the chamfer is retained, reducing the risk of wet cleaning solution penetrating into the metal gate during subsequent wet cleaning of the groove. The present invention fundamentally addresses corrosion defects caused by chemical reactions between wet cleaning solutions and metal materials such as aluminum in traditional processes, significantly enhancing the performance and reliability of the semiconductor structure.

### BRIEF DESCRIPTION OF DRAWINGS

FIG. 1 shows a schematic diagram of a process flow of a method for reducing corrosion defects in the metal gate process according to the present invention.

FIG. 2 shows a schematic structural diagram of a substrate of a method for reducing corrosion defects in a metal gate process according to the present invention.

FIG. 3 shows a schematic structural diagram of a first hard mask layer formed on a substrate of a method for reducing corrosion defects in a metal gate process according to the present invention.

FIG. 4 shows a schematic structural diagram of a chamfer formed on a substrate of a method for reducing corrosion defects in a metal gate process according to the present invention.

FIG. 5 shows a schematic structural diagram of a second hard mask layer formed on a substrate of a method for reducing corrosion defects in a metal gate process according to the present invention.

FIG. 6 shows a schematic structural diagram of a groove formed on a substrate of a method for reducing corrosion defects in a metal gate process according to the present invention.

FIG. 7 shows a schematic structural diagram of an NMOS metal grid formed on a substrate of a method for reducing corrosion defects in a metal gate process according to the present invention.

### REFERENCE NUMERALS

1 PMOS region
2 NMOS region
10 Substrate
11 P work function metal layer
12 PMOS metal gate
13 Isolation layer
14 Gate sacrificial layer
151 Sidewall
152 Interlayer dielectric layer
16 First hard mask layer
17 First photoresist layer
18 Chamfer
19 Second hard mask layer
20 Groove
21 N work function metal layer
22 NMOS metal gate
S1~S5 Steps

### DETAILED DESCRIPTION

The specific embodiments are described below to illustrate the implementation of the present invention, and those skilled in the art can easily understand other advantages and effects of the present invention from the content disclosed in this specification. The present invention can also be implemented or applied in other specific embodiments. The details provided in this description can be modified or altered in various ways based on different perspectives and applications without departing from the spirit of the present invention.

For ease of description, the schematic diagram of the device structure is not enlarged locally according to the general proportion. The diagram is merely an example and should not be construed as limiting the scope of protection of the present invention. In addition, the three-dimensional dimensions of length, width, and depth should be included in the actual manufacturing.

For ease of description, spatial relationship terms such as “below,” “under,” “lower than,” “beneath,” “above,” and “upper” may be used to describe the relationship between one component or feature shown in the diagram and other components or features. It should be understood that spatially related terms may also encompass orientations different from those depicted in the drawings, including those that occur during the use or operation of the device.

In the context of the present invention, the structure of the first feature “above” the second feature may include an embodiment where the first and second features are in direct contact, or an embodiment where another feature is positioned between them, preventing direct contact.

It should be noted that the illustrations provided in the following embodiments are merely schematic representations to explain the basic concepts of the present invention. Therefore, the figures only show components related to the present invention and are not drawn according to the actual number, shape, and size of components in practice. The actual implementation may involve variations in the type, quantity, and proportions of the components, and the layout of the components could be more complex.

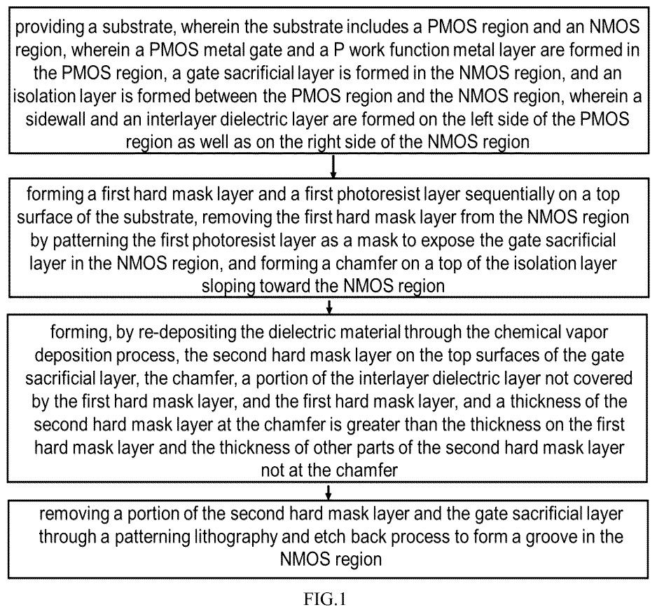

As shown in FIG. 1, the present embodiment provides a method for reducing corrosion defects in a metal gate process, and the method includes the following steps:
S1: providing a substrate 10 having a PMOS region 1 and an NMOS region 2, forming a PMOS metal gate 12 and a P work function metal layer 11 in the PMOS region 1, forming an isolation layer 13 between the PMOS region 1 and the NMOS region, and forming a sidewall 151 and an interlayer dielectric layer 152 on both a left side of the PMOS region 1 and a right side of the NMOS region 2;
S2: forming a first hard mask layer 16 and a first photoresist layer 17 sequentially on a top surface of the substrate 10, removing the first hard mask layer 16 disposed on the NMOS region using the first photoresist layer 17 as a mask to expose a gate sacrificial layer 14 in the NMOS region, and forming a chamfer 18 on a top of the isolation layer 13 sloping toward the NMOS region;
S3: forming, by re-depositing the dielectric material through the chemical vapor deposition process, the second hard mask layer 19 on the top surfaces of the gate sacrificial layer 14, the chamfer 18, a portion of the interlayer dielectric layer 152 not covered by the first hard mask layer, and the first hard mask layer 16, and a thickness of the second hard mask layer at the chamfer greater than that on the first hard mask layer;
S4: removing a portion of the second hard mask layer 19 and the gate sacrificial layer 14 through an etch back process to form a groove 20 in the NMOS region;
S5: depositing a metal material film in the groove 20 to form an N work function metal layer 21 and fill the remaining groove with an NMOS metal gate 22, and performing a chemical-mechanical polishing process to make the surfaces of the NMOS metal gate 22 and the PMOS metal gate 12 coplanar.

It should be understood that the method for reducing corrosion defects in the metal gate process mentioned in this embodiment is directed to a post-gate process, but the present invention is not limited to this. The following provides a further description of a method for reducing corrosion defects in a metal gate process with reference to the accompanying drawings, as detailed below.

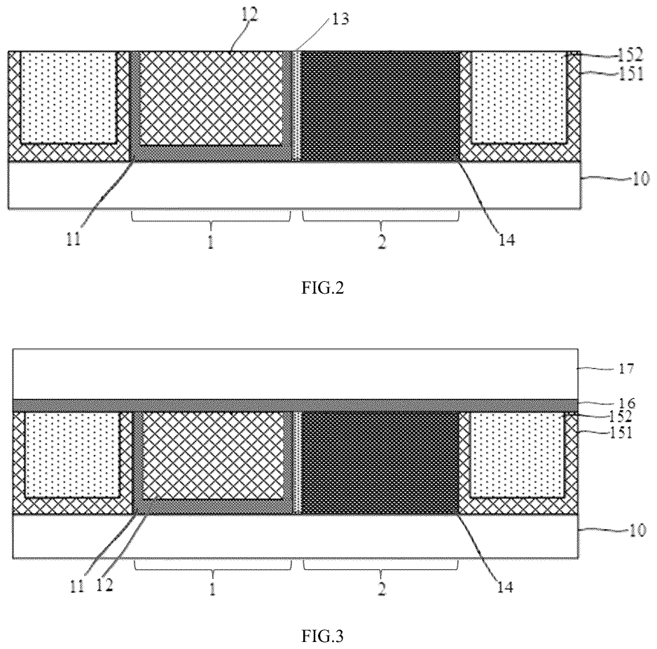

In step S1, referring to FIGS. 1 and 2, a substrate 10 is provided, and the substrate 10 has a PMOS region 1 and an NMOS region 2. A PMOS metal gate 12 and a P work function metal layer 11 are formed in the PMOS region 1. An isolation layer 13 is formed between the PMOS region 1 and the NMOS region 2. A sidewall 151 and an interlayer dielectric layer 152 are formed on both a left side of the PMOS region 1 and a right side of the NMOS region 2.

As an example, the substrate 10 may be a single crystal, polycrystalline, or amorphous silicon substrate, or a silicon-on-insulator (SOI) substrate. It may also include other types of semiconductor materials, such as germanium, silicon carbide (SiC), or silicon germanium (SiGe).

Specifically, in this embodiment, as shown in FIG. 2, the substrate 10 is selected as a conventional single crystal silicon substrate, and the PMOS region 1 and the NMOS region 2 are formed in the substrate 10. The isolation layer 13 is formed between the PMOS region 1 and the NMOS region 2. Optionally, the material of the isolation layer 13 includes any one of silicon oxide, silicon nitride, silicon oxynitride, silicon carbide, silicon carbonitride, boron nitride, tantalum nitride, or titanium nitride. For example, the isolation layer 13 may be a titanium nitride layer, and details are not repeated herein. The sidewall 151 and the interlayer dielectric layer 152 surrounded by the sidewall 151 are formed on both the left side of the PMOS region 1 and the right side of the NMOS region 2. The sidewall 151 is provided in contact with the substrate 10. Optionally, the material of the sidewall 151 includes at least one of silicon nitride and silicon dioxide, and the material of the interlayer dielectric layer 152 includes silicon oxide, silicon nitride, or other suitable dielectric materials. Specifically, in this embodiment, the material of the sidewall 151 is silicon nitride, and the material of the interlayer dielectric layer 152 is silicon oxide.

As examples, methods for forming the P work function metal layer 11 include sputtering, physical vapor deposition, chemical vapor deposition, metal-organic chemical vapor deposition, molecular beam epitaxy, atomic vapor deposition, atomic layer deposition or any other suitable techniques.

Specifically, in this embodiment, the material of the P work function metal layer 11 is titanium nitride (TiN). The P work function metal layer 11 adjusts an effective work function of the formed semiconductor structure, so that Fermi level in the PMOS region 1 is close to the top of the valence band of the substrate 10, thereby enabling the metal gate process to be compatible with the semiconductor manufacturing process. A thickness of the P work function metal layer 11 can be determined according to the actual situation.

As shown in FIG. 2, the PMOS metal gate 12 is formed above the P work function metal layer 11. The material of the PMOS metal gate 12 includes aluminum, and the NMOS region is filled with a gate sacrificial layer 14. A planarization process is performed on tops of the PMOS metal gate 12 and the gate sacrificial layer 14 to form a flat surface, thereby improving the yield of the formed semiconductor structure. Non-limiting examples of planarization methods include mechanical planarization and chemical-mechanical polishing planarization. Generally, the chemical mechanical planarization method is selected.

In step S 2, referring to FIGS. 1, 3, and 4, a first hard mask layer 16 and a first photoresist layer 17 are sequentially formed on a top surface of the substrate 10. The first hard mask layer 16 on the NMOS region is removed by using the first photoresist layer 17 as a mask to expose the gate sacrificial layer 14 in the NMOS region, and a chamfer 18 is formed on a top of the isolation layer 13.

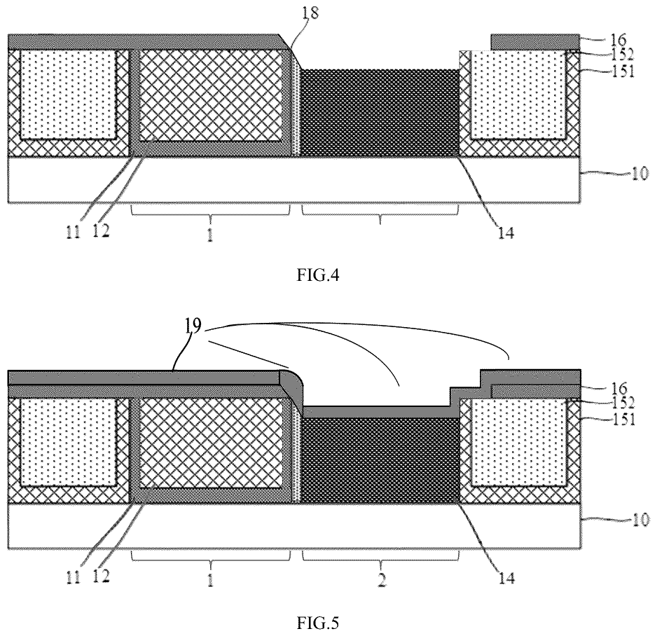

Specifically, the first hard mask layer 16 is formed by depositing a dielectric material on a top surface of the substrate 10 through a chemical vapor deposition process. The first hard mask layer 16 covers the tops of the PMOS region 1 and the NMOS region 2, and serves as a protective layer for the PMOS region 1 when subsequently patterning and etching the gate sacrificial layer 14 in the NMOS region. Then, a first photoresist layer 17 is formed by depositing a photoresist on the first hard mask layer 16. A photolithography process patterns the first hard mask layer 16 above the NMOS region and forms a notch on the isolation layer 13 through developing the first photoresist layer 17 as a mask, As shown in FIG. 3, the first hard mask layer 16 above the NMOS region is etched through a dry etching process following the photolithography to expose the gate sacrificial layer 14 in the NMOS region, and the residue first photoresist layer 17 is removed afterward. It should be noted that, as shown in FIG. 4, during the removal of the first hard mask layer 16 using the dry etching process, a top portion of the gate sacrificial layer 14 in the NMOS region and a top portion of the isolation layer 13 are etched away, and a chamfer 18 is formed on the top edge of the isolation layer 13. Since the gate sacrificial layer 14 will be further etched and removed in subsequent process steps, the partial removal of the gate sacrificial layer 14 at this stage does not affect the subsequent process.

Specifically, the residue first photoresist layer 17 can be removed by an ashing method.

As an example, the material of the first hard mask layer 16 includes at least one of silicon oxide, silicon nitride, silicon oxynitride, tantalum nitride, or titanium nitride. For instance, the first hard mask layer 16 can be titanium nitride.

In step S3, referring to FIGS. 1 and 5, a second hard mask layer 19 is formed on the top surface, covering the gate sacrificial layer 14, the first hard mask layer 16, a portion of the interlayer dielectric layer 152 not covered by the first hard mask layer 16, and the chamfer 18. Sitting at the corner of the first hard mask layer 16, the chamfer 18 gets a higher deported material than the other parts of the second hard mask layer, so the thickness of the second hard mask layer 19 at the chamfer 18 is greater than the thickness on the other parts of the second hard mask layer 19, as well as the first hard mask layer 16.

Specifically, as shown in FIG. 5, forming, by re-depositing the dielectric material through the chemical vapor deposition process, the second hard mask layer 19 on the top surfaces of the gate sacrificial layer 14, the chamfer 18, a portion of the interlayer dielectric layer 152 not covered by the first hard mask layer 16, and the first hard mask layer 16. Due to the characteristic of the chemical vapor deposition process that tends to deposit a thicker layer at around-corner regions, the thickness of the second hard mask layer 19 at the chamfer 18 is greater than the thickness on the other parts of the second hard mask layer 19 and the thickness of the first hard mask layer 16. During the etching and removal of the second hard mask layer 19, the portion of the second hard mask layer 19 around the chamfer 18 is partially removed, while the remaining second hard mask layer 19 protects the original chamfer 18, preventing the wet cleaning solution from penetrating through the chamfer 18 into the PMOS metal gate during subsequent wet cleaning processes. Consequently, it fundamentally eliminates the issue of corrosion defects caused by chemical reactions between the wet cleaning solution and the metal materials.

As an example, the thickness of the second hard mask layer 19 ranges from 1 to 10 nm. For instance, the thickness of the second hard mask layer 19 may be 1 nm, 5 nm, or 10 nm to reinforce the chamfer 18 without being too thick, which would increase the complexity of the subsequent removal process.

As an example, the material of the second hard mask layer 19 includes at least one of silicon oxide, silicon nitride, silicon oxynitride, tantalum nitride, or titanium nitride. Additionally, the material of the first hard mask layer 16 is preferred similar to that of the second hard mask layer 19. Thus, when titanium nitride is chosen for the first hard mask layer 16, the second hard mask layer 19 can also be titanium nitride to simplify subsequent etching processes.

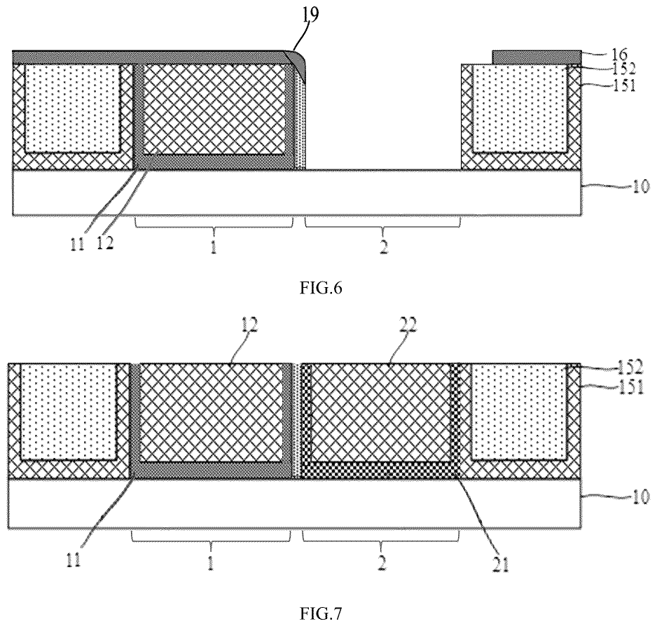

In step S4, referring to FIGS. 1 and 6, most of the second hard mask layer 19 except the chamfer and the gate sacrificial layer 14 are removed through an etch back process to form a groove 20 in the NMOS region.

Specifically, the steps for removing most of the second hard mask layer 19 and the gate sacrificial layer 14 include: removing the second hard mask layer 19 on the first hard mask layer 16 and the gate sacrificial layer 14 through a first dry etching process, as shown in FIG. 6, during which only a portion of the second hard mask layer 19 above the chamfer 18 location is retained to protect the chamfer 18; and then removing the gate sacrificial layer 14 through a second dry etching process and treating the bottom surface and side surfaces of the groove 20 to clean up process residues. The composition, flow rate, and process conditions of the etching gases applied in the first dry etching process and the second dry etching process can be selected and adjusted according to actual needs, and thus, no further detailed explanation is provided herein.

The second dry etching process employs an etching method with a high etch selectivity ratio between the gate sacrificial layer 14 and the second hard mask layer 19, such that the retained second hard mask layer 19 is protected from being etched. The PMOS metal gate 12 is not etched during the second dry etching process.

Optionally, the material of the gate sacrificial layer 14 includes one of amorphous silicon or amorphous carbon. For instance, if the gate sacrificial layer 14 is amorphous silicon, after the second dry etching process is used to remove the gate sacrificial layer 14 and form the groove 20, a cleaning step is performed on the groove 20 to ensure the complete removal of amorphous silicon and any process residues. Due to the presence of the second hard mask layer 19, the wet cleaning solution cannot penetrate through the chamfer 18 into the PMOS metal gate 12, fundamentally eliminating the issue of corrosion defects caused by chemical reactions between the wet cleaning solution and the metal material.

In step S5, referring to FIGS. 1 and 7, depositing a metal material film in the groove 20 to form an N work function metal layer 21 and fill the remaining groove with an NMOS metal gate 22. The surfaces of the NMOS metal gate 22 and the PMOS metal gate 12 are made coplanar through a chemical-mechanical polishing process.

As examples, methods for forming the N work function metal layer 21 and the NMOS metal gate 22 include sputtering, metal-organic chemical vapor deposition, molecular beam epitaxy, atomic vapor deposition, atomic layer deposition or any other suitable techniques. Specifically, in this embodiment, before depositing the NMOS metal gate 22, the N work function metal layer 21 is formed in the groove 20 using the sputtering method. In this embodiment, TiAl is chosen as the material for the N work function metal layer 21. The N work function metal layer 21 is used to adjust the effective work function of the semiconductor structure, so that the Fermi level of the NMOS region is close to a bottom of the valence band of the substrate 10. The thickness of the N work function metal layer 21 may be determined according to the actual situation.

Subsequently, the NMOS metal gate 22 is formed by depositing metal material in the groove 20. The material of the PMOS metal gate 12 is similar to that of the NMOS metal gate 22. Finally, the remaining first hard mask layer 16 and the portion of the second hard mask layer on the chamfer are removed through a chemical-mechanical polishing process to make the surfaces of the NMOS metal gate 22 and the PMOS metal gate 12 coplanar.

In another embodiment of the present invention, a semiconductor structure is further provided, as shown in FIG. 7. The semiconductor structure is formed by using the method for reducing corrosion defects in the metal gate process described above.

In summary, the method for reducing corrosion defects in the metal gate process and the semiconductor structure of the present invention includes forming a chamfer on the top edge of the isolation layer between the PMOS and NMOS regions sloping toward the NMOS region, and forming a second hard mask layer on the chamfer, as the characteristic of the deposition process creates a thicker coverage at a stepped or round the corner area, the chamfer is protected during later etching. By precisely controlling the etching thickness during subsequent steps, the second hard mask layer in flat regions is removed, while the second hard mask layer at the chamfer is only partially removed, with the remaining second hard mask layer at the chamfer retained to reinforce the chamfer, thereby reducing the risk of wet cleaning solution penetrating into the metal gate during subsequent wet cleaning of the groove. The present invention fundamentally addresses corrosion defects caused by chemical reactions between wet cleaning solutions and metal materials such as aluminum in traditional processes, significantly enhancing the performance and reliability of the semiconductor structure. The present disclosure effectively addresses the limitations of existing technologies, making it highly valuable for industrial applications.

The embodiments described above serve merely as illustrative examples of the principles and effects of the present invention, and are not intended to serve as limitations on the present invention. Persons skilled in the art may modify or alter these embodiments without departing from the spirit and scope of the present invention. Accordingly, all equivalent modifications or alterations accomplished by persons having ordinary knowledge in the art without departing from the spirit and technical ideas disclosed herein shall still be covered by the claims of the present invention.

1. A method for reducing corrosion defects in a metal gate process, comprising following steps:
providing a substrate, wherein the substrate includes a PMOS region and an NMOS region, wherein a PMOS metal gate and a P work function metal layer are formed in the PMOS region, and an isolation layer is formed between the PMOS region and the NMOS region, wherein a sidewall and an interlayer dielectric layer are formed on both a left side of the PMOS region and a right side of the NMOS region;
forming a first hard mask layer and a first photoresist layer sequentially on a top surface of the substrate, removing the first hard mask layer on the NMOS region using the first photoresist layer as a mask to expose a gate sacrificial layer in the NMOS region, and forming a chamfer on a top edge of the isolation layer sloping toward the NMOS region;
forming a second hard mask layer on the gate sacrificial layer and the first hard mask layer, and a thickness of the second hard mask layer at the chamfer is greater than a thickness of the first hard mask layer;
removing the second hard mask layer except a portion on the chamfer, and removing the gate sacrificial layer, both through an etch back process to form a groove in the NMOS region;
depositing a metal material in the groove to form an N work function metal layer and an NMOS metal gate, and performing a chemical-mechanical polishing process to make the surfaces of the NMOS metal gate and the PMOS metal gate coplanar.

2. The method according to claim 1, wherein a material of the P work function metal layer comprises TiN, and a material of the N work function metal layer comprises TiAl.

3. The method according to claim 1, wherein a material of the PMOS metal gate is similar to that of the NMOS metal gate, and a material of the PMOS metal gate comprises aluminum.

4. The method according to claim 1, wherein a material of the first hard mask layer comprises at least one of silicon oxide, silicon nitride, silicon oxynitride, tantalum nitride, or titanium nitride, and wherein a material of the second hard mask layer comprises at least one of silicon oxide, silicon nitride, silicon oxynitride, tantalum nitride, or titanium nitride.

5. The method according to claim 4, wherein the material of the first hard mask layer is similar to the material of the second hard mask layer.

6. The method according to claim 4, wherein a thickness of the second hard mask layer not at the chamfer ranges from 1 to 10 nm.

7. The method according to claim 1, wherein the steps for removing the second hard mask layer and the gate sacrificial layer through the etch back process further comprise: removing the second hard mask layer from the first hard mask layer through a first dry etching process, wherein the second hard mask layer on the chamfer is only partially removed, leaving a portion of the second hard mask layer on the chamfer retained; and then removing the gate sacrificial layer through a second dry etching process, and removing process residues from the side surface and the bottom surface of the groove..

8. The method according to claim 7, wherein the second dry etching process employs an etching method with a high etch selectivity of the gate sacrificial layer relative to the second hard mask layer.

9. The method according to claim 1, wherein the material of the gate sacrificial layer comprises one of amorphous silicon or amorphous carbon.

10. A semiconductor structure, wherein the semiconductor structure is formed by using the method for reducing corrosion defects in the metal gate process according to claim 1.
